(19) United States
(12) Patent Application Publication
(10) Pub. No.: US 2008/0302408 A1
(43) Pub. Date: Dec. 11, 2008

(54) METHOD OF MANUFACTURING AN INTEGRATED SOLAR ROOFING TILE

(75) Inventors: Peter Bressler, Philadelphia, PA (US); Seth Galewyrick, Philadelphia, PA (US); Edward Siahaan, Philadelphia, PA (US); Abby Nessa Feinstein, Philadelphia, PA (US); David Wachob, New Hope, PA (US); Martin Low, Collegeville, PA (US); Jonathan D. Albert, Philadelphia, PA (US)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: SOLAR ROOFING SYSTEMS, INC.,, Philadelphia, PA (US)

(21) Appl. No.: 12/134,040

(22) Filed: Jun. 5, 2008

Related U.S. Application Data
(60) Provisional application No. 60/942,112, filed on Jun. 5, 2007.
(60) Provisional application No. 60/942,124, filed on Jun. 5, 2007.
(60) Provisional application No. 60/942,151, filed on Jun. 5, 2007.

(51) Int. Cl. H01L 31/042

(52) U.S. Cl. 136/251

(57) ABSTRACT

A method of manufacturing a photovoltaic roofing tile for installing on a roof surface and converting solar energy into electrical energy includes the steps of forming a generally flexible photovoltaic laminate, the laminate including a photovoltaic layer including plurality of electrically interconnected photovoltaic cells and a photovoltaic circuit electrically connecting the photovoltaic cells, inserting the laminate into a tile mold and injecting a molten thermoplastic material into the tile mold to form and fixedly attached a tile base to the laminate.

### CROSS-REFERENCE TO RELATED APPLICATIONS

This application claims the benefit of U.S. Provisional Patent Application No. 60/942,151 filed Jun. 5, 2007 entitled “Solar Roofing Connector System”, U.S. Provisional Patent Application No. 60/942,112 filed Jun. 5, 2007 entitled “Solar Roofing Tile Connection System” and U.S. Provisional Patent Application No. 60/942,124 filed Jun. 5, 2007 entitled “Solar Roofing Tile”.

### BACKGROUND OF THE INVENTION

The present invention relates to a method of manufacturing a solar roofing tile, specifically a method of manufacturing a solar roofing tile in which a photovoltaic cell and circuitry is laminated and is then inserted molded into a base tile substrate.

Photovoltaic cells, formed of single crystal and/or thin film sub-modules, convert solar energy into electrical energy. Various systems have been introduced to adapt photovoltaic cells for installation onto commercial and residential roofs. Because roofing tiles are subject to harsh environmental conditions, photovoltaic modules were originally comprised of ridged materials such as metal and glass to prevent or at least postpone the hassle and expense of photovoltaic tile replacement. Such photovoltaic modules, however do not provide for a visually consistent roof and detracted from the appearance of the home or business.

Aesthetics is generally a high priority for developers and homeowners in the market for a new roof. Conventional photovoltaic modules are generally arranged in thick raised boxes with a shinny outer surface. In addition to being conspicuous, conventional photovoltaic modules required separate installation requiring the user to drill holes or other attachment means to the roof creating additional expense and potential leakages.

Roofing products have been developed that integrate the photovoltaic cells directly into individual roofing tiles or shingles which are assembled to form an integrated solar roofing system. Laminated photovoltaic modules have been introduced to produce thinner and more integrated solar roofing systems but attempts are not visually consistent with inactive tiles, are subject to de-lamination or detachment, and require special installation steps.

There is therefore a need to provide an improved integrated photovoltaic tile that has an appearance and installation similar to adjacent inactive tiles to provide for an easy to install, visually seamless roof. Additionally, the photovoltaic tiles must be sufficiently durable to withstand de-lamination or detachment and wind and water damage caused by harsh weather conditions. Ultimately there is a need to provide a photovoltaic tile that has a similar appearance, strength characteristics, and installation method of a conventional roofing product.

### BRIEF SUMMARY OF THE INVENTION

Briefly stated, the present invention is directed to a method of manufacturing a photovoltaic roofing tile for installing on a roof surface and converting solar energy into electrical energy. The method includes the steps of forming a generally flexible photovoltaic laminate, the laminate including a photovoltaic layer including plurality of electrically interconnected photovoltaic cells and a photovoltaic circuit electrically connecting the photovoltaic cells, inserting the laminate into a tile mold and injecting a molten thermoplastic material into the tile mold to form and fixedly attached a tile base to the laminate.

In another aspect, the invention is directed to a method of manufacturing a photovoltaic roofing tile for installing on a roof surface and converting solar energy into electrical energy. The method includes the steps of forming a generally flexible photovoltaic laminate via a vacuum laminate process, the laminate including a photovoltaic layer including plurality of electrically interconnected photovoltaic cells capable of receiving solar energy and a photovoltaic circuit electrically connecting the photovoltaic cells, first and second laminate sheets sandwiching and sealing the photovoltaic layer, mounting a back sheet to the laminate, inserting the laminate into a tile mold and injecting a molten thermoplastic into a second side of the tile mold to form a base tile, the thermoplastic contacting and fixing the base tile to the back sheet.

### BRIEF DESCRIPTION OF THE SEVERAL VIEWS OF THE DRAWINGS

The foregoing summary, as well as the following detailed description of a preferred embodiment of the invention, will be better understood when read in conjunction with the appended drawings. For the purpose of illustrating the invention, there is shown in the drawings an embodiment which is presently preferred. It should be understood, however, that the invention is not limited to the precise arrangements and instrumentalities shown. In the drawings:

FIG. 1 is a top perspective view of an installed integrated solar roofing system in accordance with the preferred embodiment of the present invention partially cut away to show the underlying battens and female connectors;

FIG. 2 is a top perspective view of a photovoltaic roofing tile of the integrated solar roofing system shown in FIG. 1;

FIG. 3 is an exploded perspective view of a photovoltaic laminate of the photovoltaic roofing tile shown in FIG. 2;

FIG. 4 is a perspective view of a mold for manufacturing the photovoltaic roofing tile shown in FIG. 2;

FIG. 5 is a perspective view of a non-photovoltaic roofing tile of the integrated solar roofing system shown in FIG. 1;

FIG. 6 is an exploded perspective view of the non-photovoltaic roofing tile shown in FIG. 5;

FIG. 7 is an exploded perspective view of the female connectors and battens shown in FIG. 1;

FIG. 8 is a top perspective view of the assembled female connectors and battens shown in FIG. 1 with the photovoltaic and non-photovoltaic tiles removed;

FIG. 9 is a top perspective view of female connectors and solar roofing battens shown in FIG. 1 during installation using a batten sheet;

FIG. 10 is an enlarged top perspective view of a female connector extending from a batten shown in FIG. 1;

FIG. 11 is a bottom perspective view of the female connector and batten shown in FIG. 10;

FIG. 12 is a rear cross-sectional perspective view of the female connector and batten shown in FIG. 10 taken along line 12-12 in FIG. 10;

FIG. 13 is a side cross-sectional perspective view of the female connector shown in FIG. 10 taken along line 13-13 in FIG. 10;

FIG. 14 is a side elevational partial cross section view of a photovoltaic roofing tile, batten and female connector shown in FIG. 1 just prior to installation of the photovoltaic roofing tile; and

FIG. 15 is a side elevational partial cross section view of the photovoltaic tile, batten and female connector shown in FIG. 14 after installation of the photovoltaic tile.

### DETAILED DESCRIPTION OF THE INVENTION

Certain terminology is used in the following description for convenience only and is not limiting. The words “right”, “left”, “lower” and “upper” designate directions in the drawings to which reference is made. The words “inwardly” and “outwardly” refer to directions toward and away from, respectively, the geometric center of an integrated solar roofing tile in accordance with the present invention, and designated parts thereof. Unless specifically set forth herein, the terms “a”, “an” and “the” are not limited to one element but instead should be read as meaning “at least one”. The terminology includes the words noted above, derivatives thereof and words of similar import.

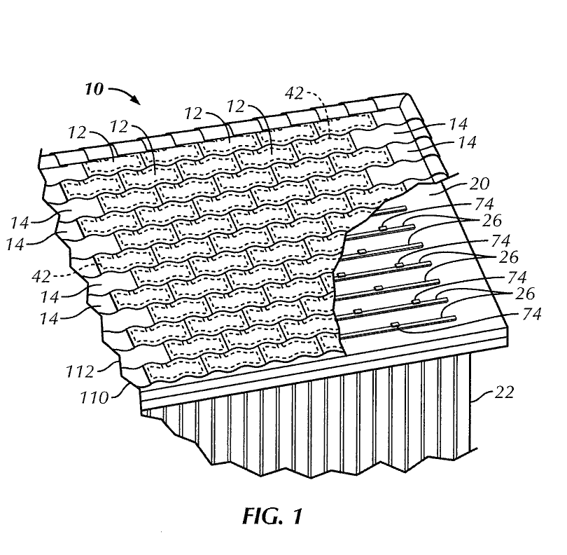

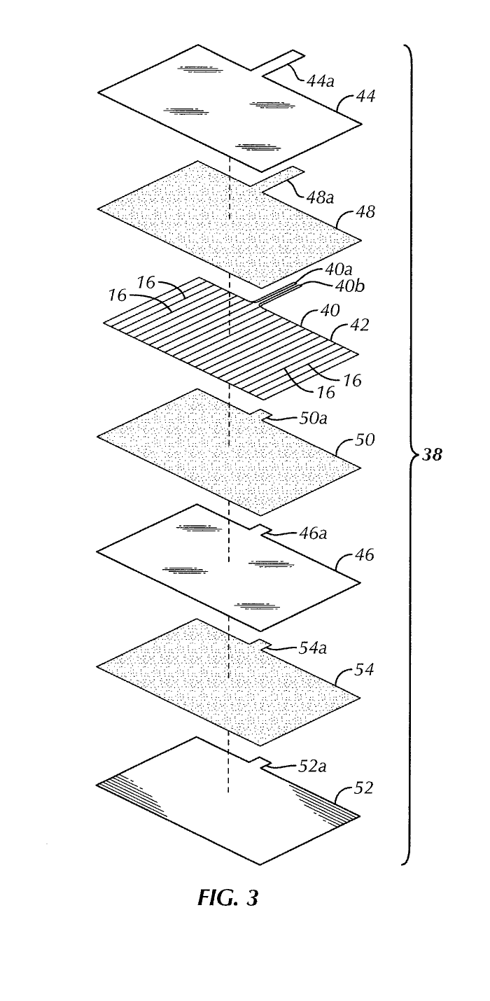

Referring to FIG. 1, the integrated solar roofing system, generally designated 10, is used to generate electricity from solar energy on a roof or roof surface 20 of a residential or a commercial building 22. The integrated solar roofing system 10 is comprised of active or photovoltaic roofing tiles 12 and inactive or non-photovoltaic roofing tiles 14. In FIG. 1, the photovoltaic roofing tiles 12 are shown having a phantom interior outline designating a photovoltaic layer 42. However, the photovoltaic roofing tiles 12 preferably have the same or a similar appearance to the non-photovoltaic roofing tiles 14 and the variation in appearance in the drawings is for demonstrative purposes only. The photovoltaic roofing tiles 12 have the same or a similar appearance and configuration to the non-photovoltaic roofing tiles 14 but the photovoltaic roofing tiles 12 include at least one photovoltaic cell 16 (FIG. 3) for generating electricity. The photovoltaic roofing tiles 12 are grouped in an area on the roof 20 that is a desired area for generating electricity. The area could be small, involving only a few photovoltaic roofing tiles 12 or the entire roof 20 depending on cost, location of the roof 20 relative to the sun and obstacles such as trees or a neighboring building blocking the sun. For example, most users in North America may choose to place the photovoltaic roofing tiles 12 only on the south facing side of a roof 20 because of the extended exposure from the south due to the earth's tilt relative to the sun. The photovoltaic roofing tiles 12 and the non-photovoltaic roofing tiles 14 preferably have an oscillating or curved shape to resemble conventional ceramic roof tiles. However, the photovoltaic roofing tiles 12 and the non-photovoltaic roofing tiles 14 may be formed in any shape such as a flat slate-like tile for example.

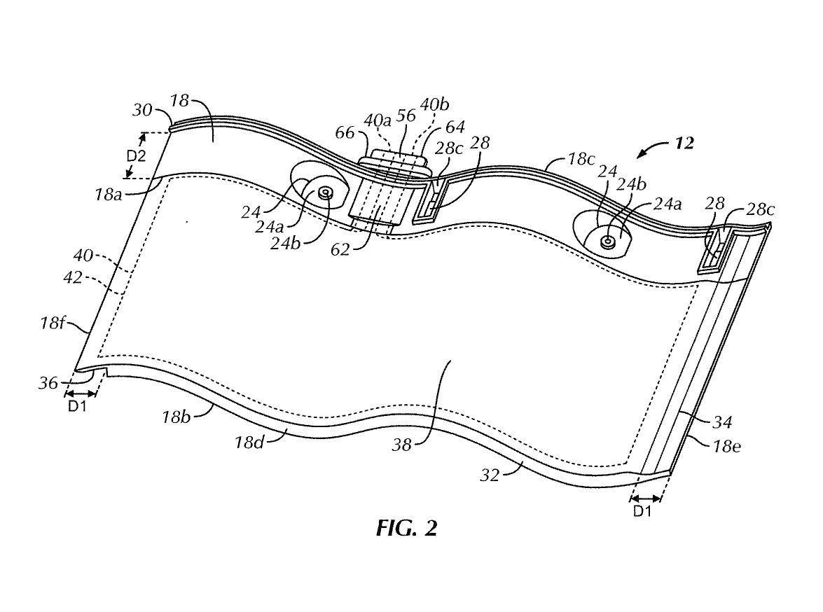

Referring to FIGS. 2-4, each photovoltaic roofing tile 12 is preferably comprised of a tile base 18 which is constructed of building code approved material. The tile base 18 has a sun or first side 18a, a roof or second side 18b, an upper or top edge 18c, a lower or bottom edge 18d, a first lateral side 18e and a second lateral side 18f. The tile base 18 is preferably constructed of an inserted molded polypropylene material, as discussed further below but the tile base 18 may be constructed of any suitable roofing material such as authentic slate, authentic ceramic tile, authentic cement tile, metal roofing, asphalt roofing, Elastocast (BASF), Bayflex (Bayer Material Science), Zytrel and/or Hytrel (Dupont). The tile base 18 may also be metallic, mineral, organic, polymeric, or a nondisclosed composite material.

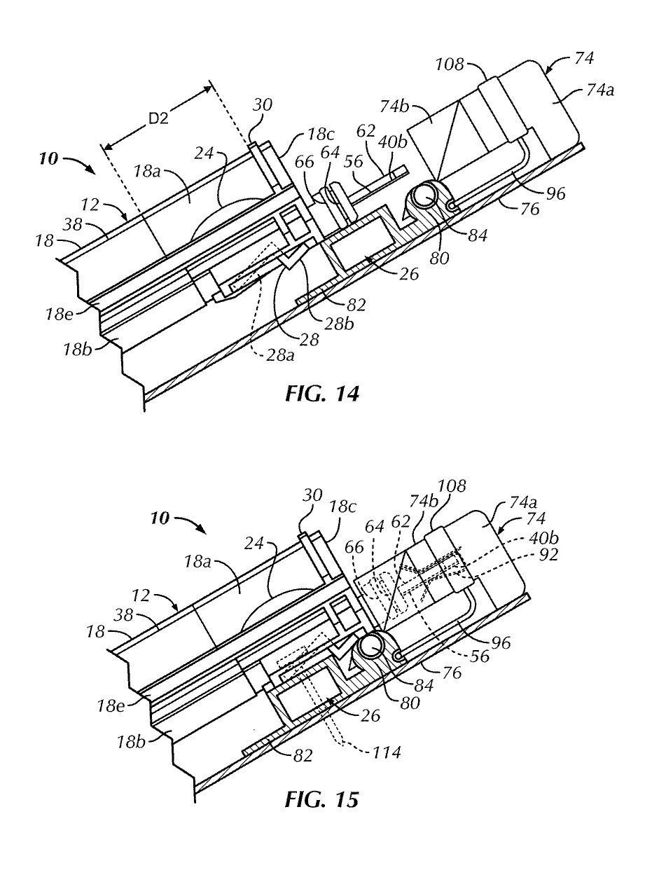

The tile base 18 preferably includes at least one and preferably a pair of recessed space apart nail targets 24 located toward the top edge 18c of the tile base 18. Each nail target 24 preferably has a flat base 24a to provide a large surface in direct contact with a batten 26 (FIG. 1) and helps to prevent the photovoltaic roofing tile 18 from lifting from the roof surface 20 in heavy winds. The nail target 24 preferably also includes a raised nail hole 24b. The nail hole 24b is raised to help prevent any water that may have entered the recessed nail target 24 from entering the nail hole 24. The tile base 18 further preferably includes at least one and preferably a pair of spaced apart, spring biased batten latches 28 proximate the top edge 18c and preferably spaced alternately between the nail targets 24 for temporarily and releasably engaging with a batten 26 during installation to hold the photovoltaic roofing tile 12 in place until the photovoltaic roofing tile 12 is more permanently secured to the batten 26 as described in further detail below. The batten latches 28 preferably each have a general Z-shape (in side view, see FIG. 14) with a longer proximal end 28a that is attached to the tile base 18 (see FIGS. 14 and 15). The batten latches 28 are each preferably upwardly angled at least at the distal end 28b of each batten latch 28. The distal end 28b at least partially extends away from the tile base 18 further than the lowest point of the tile base 18. The batten latches 28 are each spring biased such that the distal end 28b is capable of being urged upwardly and into a batten latch recess 28c (See FIG. 2) within the tile base 18 such that the batten latch 28 does not extend past the tile base 18. The batten latch 28 is preferably molded of the same or similar material as the tile base 18 and has a relatively thin proximal end 28a such that the batten latch 28 may be broken free from the tile base 18 as described further below. Though it is preferred that the batten latches 28 are molded of the same or similar material as the tile base 18, the batten latches 28 may be molded of a different material such as metal and either insert molded or otherwise later installed or assembled to the tile base 18. The batten latches 28 and the recessed nail targets 24 are preferably configured such that when the photovoltaic roofing tiles 12 are stacked on top of one another during shipping and storage, the downwardly projecting portions of the recessed nail targets 24 and the batten latches 28 are received within the recessed nail targets 24 and the batten latches 28 respectively of the photovoltaic roofing tile 12 directly below such that the photovoltaic roofing tiles 12 are nestable and form a compact stack. The compactness of the stacked photovoltaic roofing tiles 12 allows for more photovoltaic roofing tiles 12 to be shipped and/or stored on a palette (not shown) and occupy a space similar in size to what a stack of conventional roof tiles (not shown) would occupy.

A first ridge 30 preferably extends away from the first side 18a of the tile base 18 proximate the top edge 18c. A second ridge 32 preferably extends away from the second side 18b of the tile base 18 proximate the bottom edge 18d. The first and second ridges 30, 32, act as dams or barriers when the photovoltaic roofing tiles 12 are installed to prevent wind driven rain or moisture from extending beyond and eventually underneath the overlapping photovoltaic roofing tiles 12. The tile base 18 also preferably includes an upwardly facing grove 34 on the first side 18a of the tile base 18 proximate the first lateral side 18e and a correspondingly shaped downwardly facing groove 36 on the second side 18b proximate the second lateral side 18f. The upwardly facing grooves 34 mate with the downwardly facing grooves 36 during installation such that the downwardly facing grooves 36 overlap the upwardly facing grooves 34 allowing an overlap of the second lateral side 18f a first overlap distance D₁ to overlap the first lateral side 18e of an adjacent photovoltaic roofing tile 12 as the photovoltaic roofing tiles 12 are installed from left to right along the roof surface 20. The orientation of the upwardly facing grooves 34 may be switched with the downwardly facing grooves 36 such that the first lateral side 18e of the photovoltaic roofing tile 12 overlaps the second lateral side 18f of an adjacent photovoltaic roofing tile 12.

Referring to FIGS. 2, 3 and 4, each photovoltaic roofing tile 12 includes a thin generally flexible photovoltaic laminate 38 fixedly mounted to the first side 18a of the tile base 18. The laminate 38 is comprised of several encapsulated layers sandwiching the thin film photovoltaic cell(s) 16 and connected circuitry 40. The circuitry 40 is preferably comprised of a tin/silver copper or simply copper bus (not shown) with various solder/flux combinations. The circuitry 40 includes first and second terminal ends 40a, 40b that extend from the laminate 38 along a contact tab 56. The photovoltaic cells 16 and circuitry form a photovoltaic layer 42. The photovoltaic layer 42 is sandwiched between a first laminate sheet 44 and a second laminate sheet 46. The first and second laminate sheets 44, 46 are preferably constructed from but not limited to ETFE fluorinated polymer Tefzel, Aklar, silicone oxide or any other water vapor barrier layers such as glass. The first laminate sheet 44 allows light into the photovoltaic cells 16 while providing a protective cover for the photovoltaic layer 42. The first laminate sheet 44 is preferably textured or otherwise treated to avoid an overly shiny or reflective surface and to better conceal the appearance of the photovoltaic layer 42. The first and second laminate sheets 44, 46 are preferably laminated to opposing sides of the photovoltaic layer 42 by first and second EVA laminate adhesive layers 48, 50. The bottommost layer of the photovoltaic laminate 38 is preferably an appliqué layer or back sheet 52 constructed of a polypropylene material or any suitable material such as EPE (ethyl vinyl acetate (EVA)/polyester/EVA). The back sheet 52 may be mounted to the second laminate sheet 44 by a third adhesive layer 54. The back sheet 52 prevents the hot material injected during molding of the tile base 18 from damaging the photovoltaic laminate 38. The first laminate sheet 44 and the first adhesive layer 48 preferably include a first laminate tab 44a and a first adhesive tab 48a respectively which each extend over the entire length of the contact tab 56. The second and third adhesive layers 50, 54, the second laminate sheet 46 and the back sheet 52 have a second adhesive tab 50a, a third adhesive tab 54a, a second laminate tab 46a and a back sheet tab 52a respectively that preferably extend only partially along the contact tab 56 until the contact tab 56 reaches the top edge 18c of the tile base 18 such that a distal end of the first and second terminal ends 40a, 40b is exposed toward the second side 18b of the tile base 18 or toward the roof surface 20. However, the first and second terminal ends 40a, 40b may be left uncovered in any direction on the contact tab 56 or in any manner such as cutting slots or holes to leave at least a portion of the first and second terminal ends 40a, 40b following the lamination process without the need for further manufacturing steps and is sufficient to allow for an electrical connection with the photovoltaic layer 42 as described further below.

The laminate 38 is preferably manufactured via a vacuum lamination process where a specific cycle of heat, vacuum, and pressure is applied to produce a flexible but durable laminate that provides outdoor and mechanical and environmental protection to the photovoltaic cell(s) 16. The photovoltaic laminate 38 is formed by assembling the photovoltaic layer 42 between the first and second laminate sheets 44, 46, with or without the first and second adhesive layers 48, 50 and then placing the stack in a vacuum laminator (not shown). Preferably, but not limiting, a platen (not shown) is set at 150° C. For approximately three minutes, both chambers then pull a vacuum for about seven minutes the upper chamber is released to atmosphere for a total cycle of about 10 minutes. Aluminum sheets (not shown) are preferably used as carrier sheets to carry the laminate 38 into and out of the laminator. A gritted surface such as sandpaper (not shown), is preferably provided on one of the carrier sheets to provide a textured surface to the first laminate sheet 44. Alternatively, the aluminum of the carrier sheets or the platen of the laminator themselves could be textured to provide the textured surface to the first laminate sheet 44. The back sheet 52 is then attached to the second laminate layer 46, preferably using the third adhesive layer 54. While a preferred series of layers for the photovoltaic laminate 38 has been described above, other arrangements of layers and other materials for the individual layers could be used to achieve the same result of securing photovoltaic cells 16 to the tile base 18.

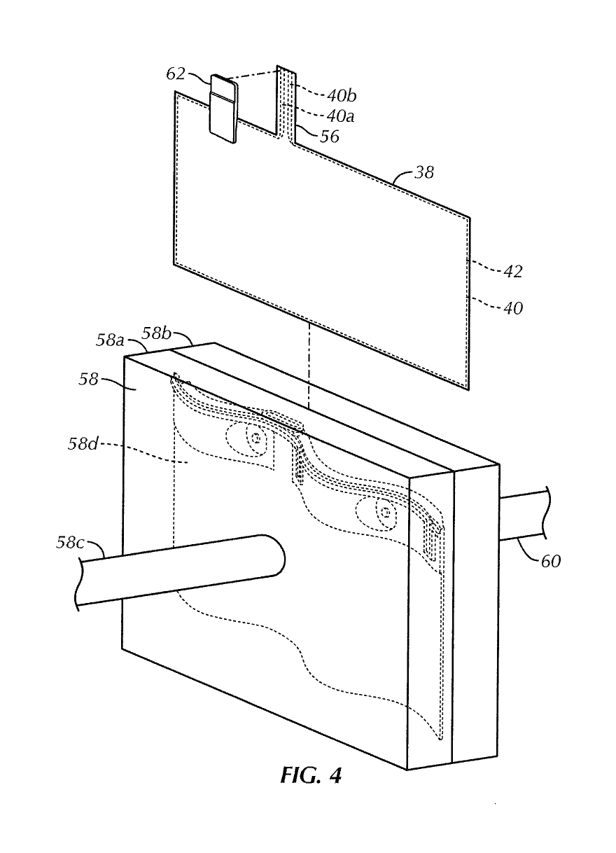

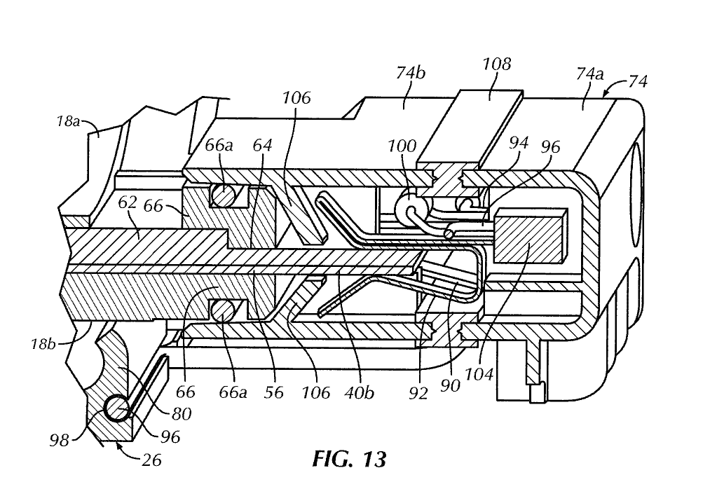

Referring to FIG. 4, once the photovoltaic laminate 38 has been assembled, the photovoltaic laminate 38 is inserted into a mold 58. The laminate 38 is preferably preheated to a predetermined temperature to prevent the photovoltaic laminate 38 from being subjected to two different heats, one on each side of the photovoltaic laminate 38, that could cause the photovoltaic laminate 38 to warp during cooling. Preheating the laminate 38 allows the laminate 38 and tile bale 18 to cool and shrink generally at a similar rate and amount. Once in place in the mold 58, the photovoltaic laminate 38 is preferably held toward a first side 58a of the mold 58 by a vacuum 58c or other means. Because the photovoltaic laminate 38 is flexible, the photovoltaic laminate 38 conforms to the shape 58d of the mold 58 (the generally shape 58d of the mold 58 is shown in phantom). A rigid contact support 62 is preferably inserted over the contact tab 56 during the molding process as well forming a male connector 64 such that the contact support 62 is positioned between the contact tab 56 and the first side 58a of the mold 58 during molding. However, the contact support 62 may be integrally formed with the tile base 18. When cooled, the contact support 62 adds stiffness to the contact tab 56 extending from the top edge 18c of the tile base 18. A molten polymeric material is then injected into the mold 58 through an injection port 60 on a second side 58b of the mold 58 to form the tile base 18 underneath the laminate 38. The back sheet 52 protects the photovoltaic layer 42 and the second laminate sheet 46 from being damaged proximate the injection port 60 where the injected material for the tile base 18 is at its highest temperature. An outwardly extending flange 66 (FIG. 2), is preferably molded around a portion the contact support 62 and the contact tab 56 proximate the top edge 18c forming a rigid male connector 64. The flange 66 preferably includes an elastomeric o-ring 66a that is assembled onto the flange 66 after the molding process (See FIG. 13). Though it is preferred that the flange 66 be integrally molded with the tile base 18, the flange 66 may be separately assembled or may be part of the contact support 62. The photovoltaic roofing tile 12 is preferably molded in a generally vertical orientation to enable gravity to assist in maintaining the proper positioning of the photovoltaic laminate 38 and the contact support 62 during the molding process. Though it is preferred that the photovoltaic laminate 38 be fixed to the tile base 18 using the insert molding process described above, the photovoltaic laminate 38 may be mounted to the tile base 18 in any suitable manner such as using an adhesive or fasteners. Once the photovoltaic roofing tile 12 has sufficiently cooled, the photovoltaic roofing tile 12 is removed from the mold 58. Once removed from the mold, it is preferred that the first and second terminal ends 40a, 40b are exposed on a bottom surface of the male connector 64 as a result of the molding process to form a rigid, integral male electrical plug or connector 64 right out of the mold 58 without the need for further steps or attachments. The first and second terminal ends 40a, 40b may be exposed through the laminate 38 in any direction on the male connector 64 so long as there is no need to perform additional steps once the photovoltaic roofing tile 12 is removed from the mold 58 such as removing material from the male connector 64 or attaching additional components.

Referring to FIG. 2, though the photovoltaic laminate 38 is generally thin, it is preferred that the photovoltaic laminate 38 be generally flush with the remainder of the first side 18a of the tile base 18. The photovoltaic laminate 38, except for the contact tab 56, is preferably spaced from the top edge 18c by a second tile overlap distance D₂. During installation, a subsequent upper row of photovoltaic roofing tiles the previous lower row of photovoltaic roofing tiles 12 by the overlap distance D₂ preferably such that only the photovoltaic laminate 38 is exposed and any portion of the first side surface 18a not covered by the photovoltaic laminate 38 is covered by an adjacent overlying photovoltaic roofing tile 12 or adjacent non-photovoltaic roofing tile 14. Spacing the photovoltaic laminate 38 from the top edge 18c allows for the nail targets 24 and batten latches 28 to extend through the base tile 18 without damaging or otherwise impacting the photovoltaic laminate 38. The photovoltaic laminate 38 preferably extends from the first lateral side 18e to the second lateral side 18f of the tile base with the photovoltaic layer 42 being spaced from the first lateral side 18e by the first overlap distance D₁. However, the photovoltaic laminate 38 need not necessarily extend from the first lateral side 18e to the second lateral side 18f and may be cover any suitable amount of the first side surface 18a such as being spaced from the first lateral side 18e by the first overlap distance D₁ to prevent being contacted by an adjacent photovoltaic roofing tile 12.

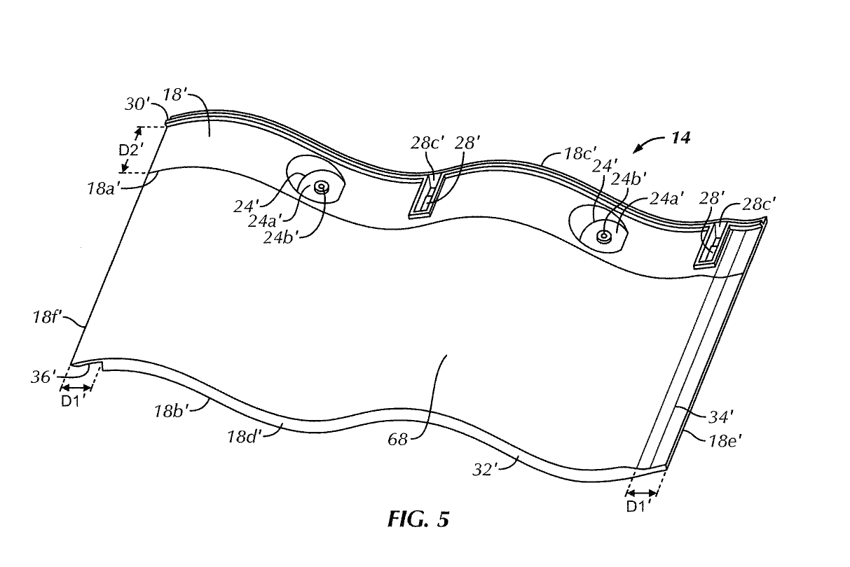

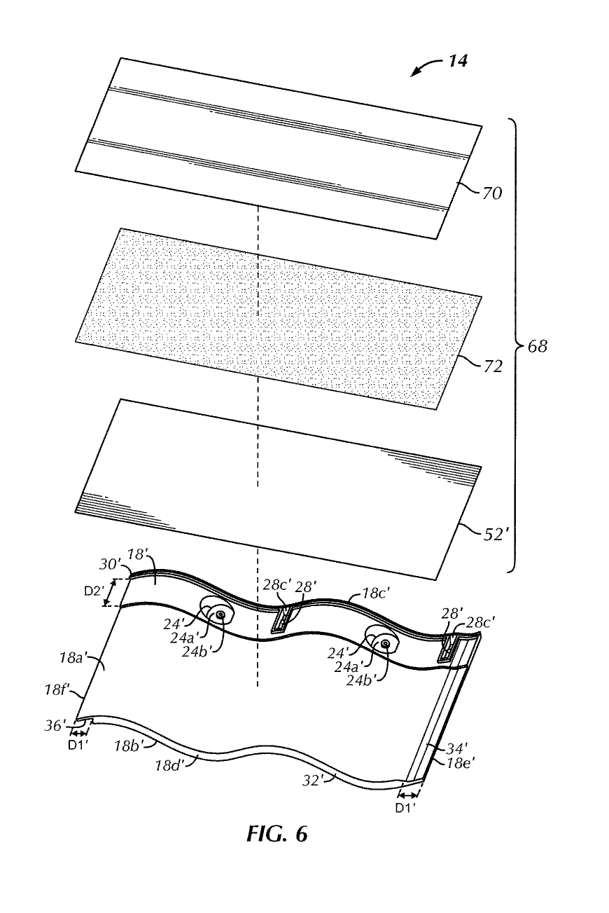

Referring to FIGS. 5 and 6, the non-photovoltaic roofing tiles 14 are configured and manufactured in a similar manner as the photovoltaic roofing tiles 12 except that the non-photovoltaic roofing tiles 14 do not include the male connector 64 and the photovoltaic laminate 38 is replaced with a cover 68. The components of the non-photovoltaic roofing tile 14 that are similar to photovoltaic roofing tile 12 have been labeled with similar numbering as the photovoltaic roofing tile 12 with the addition of a trailing prime symbol. The cover 68 is comprised of an upper layer 70, a fourth adhesive layer 72 and a back sheet 52′. The upper layer 70 is preferably a glossy layer of weatherproof paint such as the type used on automobiles. However, any suitable material may be used so long as the upper layer 70 has a similar appearance as the photovoltaic laminate 38 to help create a visually consistent roof 20 where it is not readily discernable which roofing tiles 12, 14 are the photovoltaic roofing tiles 12 and which roofing tiles 12, 14 are the non-photovoltaic roofing tiles 14. The cover 68 is preferably molded to the tile base 18′ in a similar manner as described above for the laminate 38 of the photovoltaic roofing tile 12.

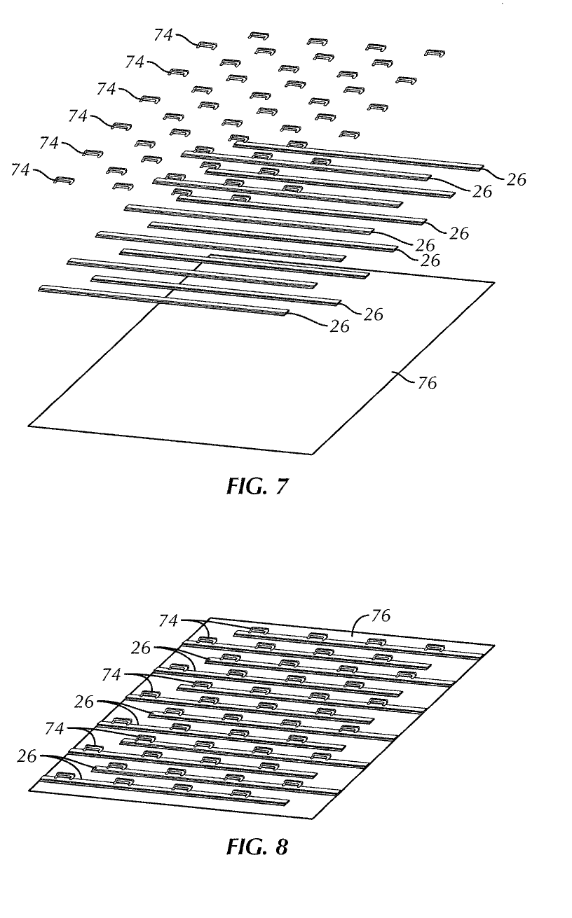

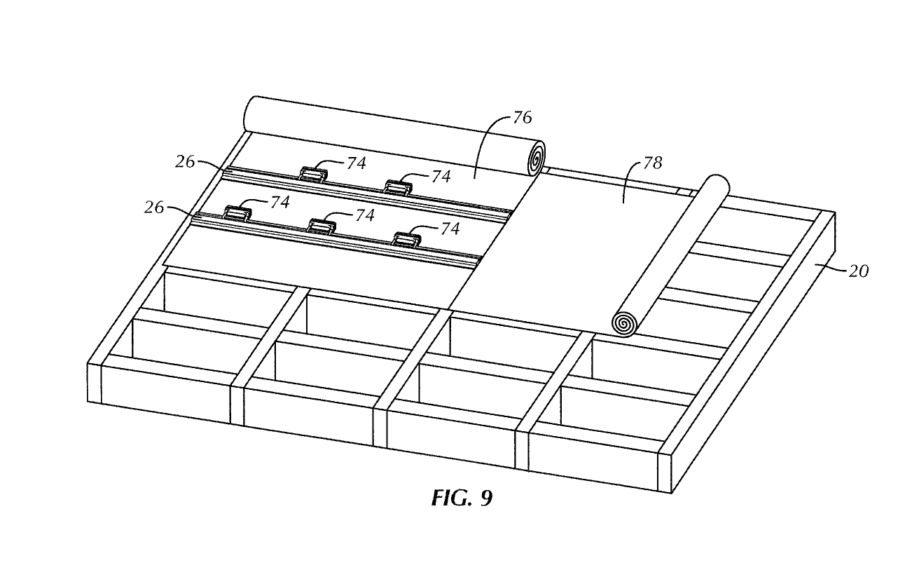

Referring to FIGS. 7-9, photovoltaic roofing tiles 12 are electrically connected to each other through a plurality of corresponding female connectors 74 and battens 26. The battens 26 are preferably custom made and replace the use of conventional battens (not shown). However, the battens 26 may alternatively be comprised of a cover (not shown) that extends over the conventional battens. The battens 26 are preferably molded of a polymeric material and are mounted to a batten sheet 76. The batten sheet 76 is preferably a flexible sheeting material similar to conventional roofing underlayments 78 (FIG. 9). The batten sheet 76 preferably includes nail markings (not shown) to indicate where the battens 26 and or photovoltaic roofing tiles 12 are to be installed. The batten sheet 76 may be used in place of the conventional underlayment 78 or the batten sheet 76 may be installed in addition to and on top of the conventional underlayment 78 (see FIG. 9). The batten sheet 76, battens 26 and female connectors 74 are preferably used only under the photovoltaic roofing tiles 12 while only conventional battens are used under the non-photovoltaic roofing tiles 14. However, the batten sheet 76 and battens 26 may extend under or be used under the non-photovoltaic roofing tiles 14 as well.

The batten sheet 76 is preferably installed with the battens 26 and female connectors 74 already attached prior to installation. Pre-installation of the battens 26 and the female connectors 74 facilitates simplified installation of the integrated solar roofing system 10 and allows for automated and precise assembly in a factory setting. However, the battens 26 and female connectors 74 may be assembled on the roof surface 20 as well. The female connectors 74 are preferably pre-installed on the respective batten 26 and the battens 26 are attached to the roof surface 20 or batten sheet 76 at the appropriate locations by the manufacturer or distributor. However, the female connectors 74 may be attached to the battens 26 during roof installation, with the spacing being measured or dictated by the location of the corresponding male connector 64. If the batten sheet 76 is installed first without pre-connected battens 26, the batten sheet 76 is installed in the same manner that the conventional underlayment 78 is installed except that the batten sheet 76 preferably includes nail markings for positioning of the battens 26. Once the batten sheet 76 is installed in an area where the photovoltaic roofing tiles 12 are to be installed, the battens 26 are nailed or otherwise secured into place and the female connectors 74 are positioned on the battens 26 where it is projected that a male connector 64 will extend from the top of the photovoltaic roofing tiles 12. The male connector 64 allows for mechanical and electrical connection of the photovoltaic cells 16 and the female connectors 74 such that adjacent photovoltaic roofing tiles 12 may be electrically connected to combine the resulting electrical energy.

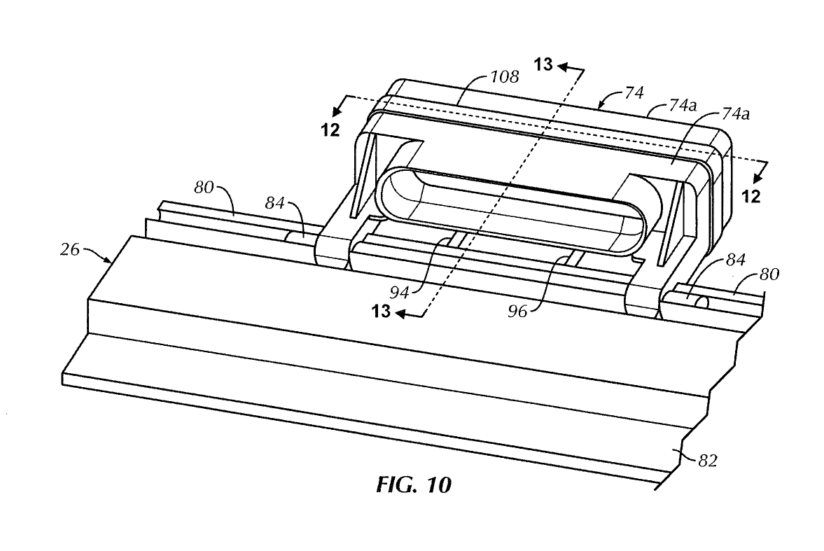

Referring to FIG. 10, each female connector 74 is preferably pivotably attached to the respective batten 26. The battens 26 each include a C-shaped pivot extension 80 extending from the upper edge of the batten 26. A nail extension 82 preferably extends from the lower edge of the batten 26 in the opposite direction from the pivot extension 80. The nail extension 82 preferably has a smaller thickness than the remainder of the batten 26 and is preferably used for receiving nails (not shown) or other fasteners for securing the batten 26 to the roof surface 20. The nail extensions 82 may include nail markings (not shown) to indicate where a nail or fastener should be inserted. The female connectors 74 preferably each include a pair of generally cylindrical pivot arms 84. The pivot arms 84 extend laterally from the remainder of the female connector 74 and are pivotably disposed within the pivot extension 80. The pivot arms 84 are preferably snap fit into the pivot extension 80 such that the female connector 74 may be easily installed and removed from the batten 26. If the female connectors 74 and battens 26 are pre-installed or temporarily secured to the batten sheet 76, the batten sheet 76 may be directly rolled, vertically upwardly rather than from left to right, onto the roof structure 20 with the battens 26 and female connectors 74 already in the appropriate positions (see FIG. 9). The pivotal connection of the female connector 74 to the batten 26 not only allows for a slight tilt of the female connector 74 during installation as described further below but the pivotal connection of the female connectors 74 with respect to the battens 26 also allows for the female connectors 74 to be at least partially folded on top of the batten 26 such that the batten sheet 76 may be rolled up with the battens 26 and female connectors 74 already in place. Once the batten sheet 76 is unrolled, the female connectors 74 pivot to lay against the batten sheet 76 due to gravity or are manually flipped down onto the batten sheet 76 by the installer prior to installation of the photovoltaic roofing tiles 12.

Referring to FIGS. 10-13, each female connector 74 includes a pair of first and second contacts 90, 92 preferably in the form of two U-shaped clips that receive and tightly engage the distal end of the male connector 64 such that the first and second terminal ends 40a, 40b are in direct and positive electrical contact with the first and second contacts 90, 92 respectively. The first and second contacts 90, 92 may have any shape capable of allowing a good electrical connection between the first and second terminal ends 40a, 40b and the first and second contacts 90, 92 and need not extend over the contact support 62. A first electrical wire 94 is connected to the first contact 90 and a second electrical wire 96 is connected to the second contact 92. The first and second electrical wires 94, 96 each include an insulating cover 94a, 96a respectively.

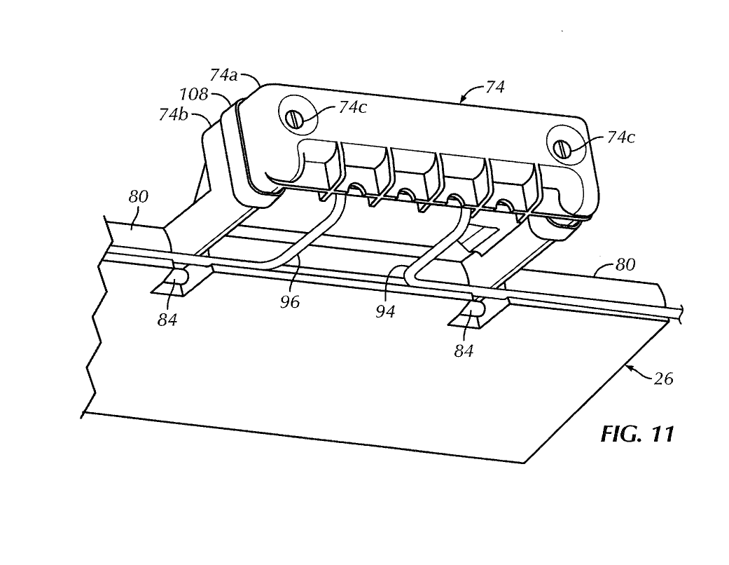

Referring to FIGS. 11 and 13, the first and second electrical wires 94, 96 are preferably contained, or at least partially contained, within the battens 26. A wire groove 98 extending into and along the pivot extension 80 is preferably provided for example for receiving and retaining the first and second electrical wires 94, 96 as they runs from one female connector 74 to the next female connector 74 along the batten 26. Though it is preferred that the first and second wires 94, 96 be contained within the pivot extension 80, the first and second electrical wires may be at least partially contained within the batten 26, within the batten sheet 76 or not restrained at all. The first and second electrical wires 94, 96 may also be integrally provided within the batten 26 and the contact between the pivot arms 84 or the like between the female connector 74 and the batten 26 could also establish an electrical connection with internal electrical wiring or electrically conductive elements (not shown). The first electrical wire 94 extends in one lateral direction along the batten 26 and the second electrical wire 96 extends in the opposite lateral direction along the batten 26 such that there is an electrical input and an electrical output to the female connector 74. The first and second electrical wires 94, 96 may extend to an adjacent or other photovoltaic roofing tile 12, off of the roof surface 20, or to any other electrical component.

A bypass diode 100 preferably extends between the first and second contacts 90, 92 such that the first and second contacts 90, 92 and the circuitry 40 in the photovoltaic layer 42 may be electrically bypassed allowing electricity to run from the first electrical wire 94 to the second electrical wire 96 without interruption in the event that the photovoltaic roofing tile 12 fails or the connection between the female connector 74 and the male connector 64 is interrupted. A first crimp sleeve 102 preferably secures the first electrical wire 94 to the first contact 90 and a second crimp sleeve 104 preferably secures the second electrical wire 96 to the second contact 92. The first and second crimp sleeves 102, 104 also preferably hold the bypass diode 100 in connection with the first and second electrical wires 94, 96.

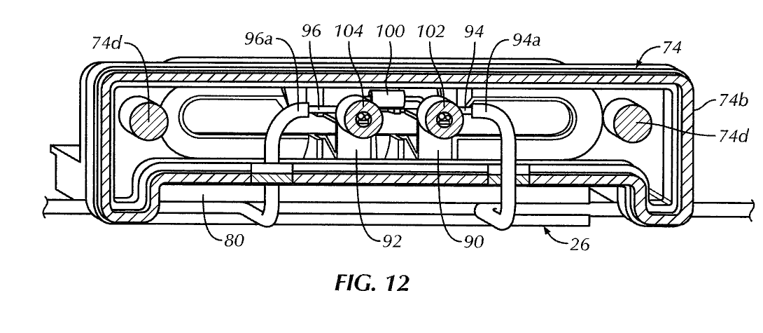

The female connector 74 is preferably comprised of a back cover 74a and receiving window 74b. The receiving window 74b is at least partially open toward the batten 26 for receiving the male connector 64 from a photovoltaic roofing tile 12, preferably allowing the only access to the first and second contacts 90, 92. The receiving window 74b preferably includes sealing ribs 106 extending toward the center of the receiving window 74b and slanted back toward the back cover 74a (FIG. 13). The back cover 74a and the receiving window 74b are preferably held together with screws 74c extending through the back cover 74a (FIG. 11) and into screw supports 74d in the receiving window 74b (FIG. 12). The back cover 74a and receiving window 74b are preferably sealed together with an elastomeric gasket 108. Though the two piece female connector 74 is preferred for assembly purposes, the female connector 74 may be comprised of one or more sections and is not limited to having a separate back cover 74a and receiving window 74b.

Referring to FIG. 13, the o-ring 66a on the flange 66 extends slightly further than the width and length of the opening of the receiving window 74b. When the male connector 64 is inserted into the female connector 74, the o-ring 66a is compressed and the flange 66 preferably engages the ribs 106 to seal the male connector 64 to the female connector 74 and prevent over insertion of the male connector 64. The flange 66 may also snap fit or be otherwise temporarily retained within the receiving window 74b. When the flange 66 is inserted into the receiving window 74b, the exposed first and second terminal ends 40a, 40b contact lower arms 90a, 92a of the first and second contacts 90, 92, respectively (FIG. 13). The contact tab 56 and the contact support 62 spread apart the first and second contacts 90, 92 to spring bias the first and second contacts 90, 92 into good electrical contact with the first and second terminal ends 40a, 40b respectively. The receiving window 74b may include a pierceable covering (not shown) or alternatively the ribs 106 may be held in compressive contact to seal the female connector 74 during assembly to further prevent a human finger (not shown) from touching the first and second contacts 90, 92 but may separate with sufficient force caused by the insertion of the male connector 64.

The female connectors 74 along a batten 26 are electrically connected by the first and second electrical wires 94, 96. The battens 26 may be configured either in parallel or series. For example, when the photovoltaic roofing tiles 12 are arranged in series, the first and second electrical wires 94, 96 runs from a female connector 74 to the next adjacent female connector 74 along one row from left to right such that the electrical wires 94, 96 do not cross (FIGS. 11 and 12). In the next row, the ends of the first and second electrical wires 94, 96 from right to left cross (not shown) such that first and second wires 94, 96 alternates between the inner most and outmost entry point of the adjacent female connector 74. Such a configuration allows for a series connection with the same photovoltaic roofing tiles 12 used throughout and prevents the installer from confusing photovoltaic roofing tiles 12 that have reversed positive and negative terminal ends 40a, 40b. Alternatively, each photovoltaic roofing tile 12, or more likely, each row of photovoltaic roofing tiles 12, may be connected in parallel. The first and second electrical wires 94, 96 may also extend to a different batten 26 or off of the roof surface 20. Regardless of the preferred configuration, the electrical schematic may be determined and assembled in a factory setting, allowing the installer to simply install the photovoltaic roofing tiles 12 similarly to the non-photovoltaic roofing tiles 14 without worrying about the electrical schematic and arrangement of the photovoltaic roofing tiles 12 other than to connect the male connector 64 of each of the photovoltaic roofing tiles 12 to the corresponding female connector 74.

Referring to FIGS. 1, 14 and 15, the photovoltaic roofing tiles 12 and the non-photovoltaic roofing tiles 14 are preferably installed in a conventional overlapping fashion. For example, a first row of tiles 110 is installed from left to right overlapping the previous photovoltaic or non-photovoltaic tile 12, 14 by a first overlap distance D₁ (FIG. 2) and then similarly installing a second row of tiles 112 from left to right that overlap the first row of tiles 110 by the second overlap distance D₂ (FIG. 2). The photovoltaic roofing tiles 12 and the non-photovoltaic roofing tiles 14 are preferably installed in a similar manner to one another in that the photovoltaic roofing tiles 12 and the non-photovoltaic roofing tiles 14 are slid upwardly on a plane spaced from and generally parallel to the roof surface 20 such that each photovoltaic and non-photovoltaic roofing tile 14 is slid across the batten 26 (see FIGS. 14 and 15). The photovoltaic roofing tiles 12 preferably differ in installation in only that the male connector 64 must be aligned with the corresponding female connector 74. The horizontal receiving port 74b of the female connector 74 allows the male connector 64 to be inserted within the female connector 74 without vertical displacement (perpendicular to the roof surface 20) of the photovoltaic roofing tile 12. As the photovoltaic roofing tile 12 is slid across the batten 26 a distal end 28b of the batten latch 28 contacts the front top edge of the batten 26 and deflects the batten latch 28 upwardly into the batten recess 28c such that the batten latch 28 is deflected out of the way and does not prohibit or limit the photovoltaic roofing tile 12 from being slid across the batten 26. Once the distal end 28b of the batten latch 28 passes the upper edge of the batten 26, the batten latch 28 returns to its initial position under its own bias such that the distal end 28b engages or latches on to the upper rear edge of the batten 26. The batten latch 28 engages with the batten 26 such that the photovoltaic roofing tile 12 is temporarily held in place and prevents the photovoltaic roofing tile 12 from sliding off of the batten 26 during installation. Simultaneously with the engagement of the batten latch 28 with the batten 26, the male connector 64 slides into the female connector 74 such that an electrical connection is established. Because the mechanical connection to the female connector 74 may not be sufficient to hold the photovoltaic tile 12 in place, the batten latch 28 ensures that the photovoltaic roofing tile 12 remains in place until a nail 114 (FIG. 15) or other fastener more is driven through the recessed nail targets 24 to more permanently secure the photovoltaic roofing tile 12 to the batten 26 and/or roof surface 20.

The horizontal installation of the photovoltaic roofing tile 12 also allows for easier removal and replacement of a defective photovoltaic roofing tile 12 without disturbing adjacent tiles 12, 14. During removal or replacement of the photovoltaic roofing tile 12, the nail 114 is removed and the batten latch 28 is either disengaged by the use of a tool (not shown) or may be broken off to allow the photovoltaic roofing tile 12 to be removed in a generally planar fashion as similar to insertion. A replacement photovoltaic roofing tile 12 is then installed similarly to the initial installation such that the photovoltaic roofing tile 12 is slid in a plane generally parallel to the roof surface 20 and the male connector 64 is inserted into the female connector 74.

Installation of the photovoltaic tiles 12 concludes by dropping two leads, positive and negative (not shown), that extend from the batten sheet 76 or the upward most solar roofing batten 26 connected to the electrical wires with “quick-connect” terminals (not shown) into the roof ridge line or through a hole drilled through the roof surface 20. The leads allow an electrician to connect one batten sheet 76 to another batten sheet 76.

It will be appreciated by those skilled in the art that changes could be made to the embodiment described above without departing from the broad inventive concepts thereof. It is understood, therefore, that this invention is not limited to the particular embodiment disclosed, but it is intended to cover modifications within the spirit and scope of the present invention as defined by the appended claims.

Further, to the extent that the assembly methods do not rely on the particular order of steps set forth herein, the particular order of the steps in the steps set forth in the preferred methods should not be construed as limitation on the claims. The claims directed to the method of the present invention should not be limited to the performance of their steps in the order written, and one skilled in the art can readily appreciate that the steps may be varied and still remain within the spirit and scope of the present invention.

I/We claim:

1. A method of manufacturing a photovoltaic roofing tile for installing on a roof surface for converting solar energy into electrical energy, the method comprising:
a) forming a generally flexible photovoltaic laminate, the laminate including a photovoltaic layer including plurality of electrically interconnected photovoltaic cells and a photovoltaic circuit electrically connecting the photovoltaic cells;
b) inserting the laminate into a tile mold; and
c) injecting a molten thermoplastic material into the tile mold to form and fixedly attached a tile base to the laminate.

2. The method of claim 1, wherein the laminate formed in step a) is formed via a vacuum lamination process.

3. The method of claim 1 further comprising the step b-2) holding the laminate to a side of the tile mold using a vacuum.

4. The method of claim 1, wherein one of a carrier sheet and a platen is textured during step a) forming a textured surface on the laminate.

5. The method of claim 1 further comprising the step of d) pre-heating the laminate prior to step b).

6. The method of claim 1 further comprising the step of d) mounting a back sheet onto the laminate prior to step b).

7. The method of claim 7 wherein the back sheet layer is constructed of polypropylene.

8. A method of manufacturing a photovoltaic roofing tile for installing on a roof surface and converting solar energy into electrical energy, the method comprising:
a) forming a generally flexible photovoltaic laminate via a vacuum laminate process, the laminate including a photovoltaic layer including plurality of electrically interconnected photovoltaic cells capable of receiving solar energy and a photovoltaic circuit electrically connecting the photovoltaic cells, first and second laminate sheets sandwiching and sealing the photovoltaic layer;
b) mounting a back sheet to the laminate;
c) inserting the laminate into a tile mold; and
d) injecting a molten thermoplastic into a second side of the tile mold to form a base tile, the thermoplastic contacting and fixing the base tile to the back sheet.

9. The method of claim 8 further comprising the step of e) pre-heating the laminate prior to step c).

10. The method of claim 8 further comprising the step of e) drawing the laminate to a first side of the mold using a vacuum prior to step d).

11. The method of claim 8 wherein the back sheet layer is constructed of polypropylene.
